(19) United States
(12) Patent Application Publication
(10) Pub. No.: US 2025/0060419 A1
(43) Pub. Date: Feb. 20, 2025

(54) ABNORMALITY DIAGNOSIS SYSTEM AND METHOD FOR A BATTERY CELL

(71) Applicants: HYUNDAI MOTOR COMPANY, Seoul (KR); KIA CORPORATION, Seoul (KR)

(72) Inventor: Sung Ho Kim, Daejeon (KR)

(73) Assignees: HYUNDAI MOTOR COMPANY, Seoul (KR); KIA CORPORATION, Seoul (KR)

(21) Appl. No.: 18/535,438

(22) Filed: Dec. 11, 2023

(30) Foreign Application Priority Data
Aug. 14, 2023 (KR) 10-2023-0106342

(51) Int. Cl. G01R 31/392; G01R 31/382; H01M 10/42; H01M 10/48

(52) U.S. Cl. CPC G01R 31/392; G01R 31/382; H01M 10/4285; H01M 10/482

(57) ABSTRACT

A system diagnoses abnormality of a battery cell of a battery. The system includes a plurality of battery cells and a sensing board connected to the plurality of battery cells. The system further includes a plurality of switches provided between each battery cell and the sensing board and configured to electrically connect or disconnect each battery cell and the sensing board. The system further includes a controller for measuring voltage of any one battery cell by electrically connecting the one battery cell among the plurality of battery cells to the sensing board and disconnecting the remaining battery cells. The controller also diagnoses each of the plurality of battery cells based on voltage drop in each battery cell.

### CROSS REFERENCE TO RELATED APPLICATION

The present application claims priority to Korean Patent Application No. 10-2023-0106342, filed Aug. 14, 2023, the entire contents of which are incorporated herein for all purposes by this reference.

### TECHNICAL FIELD

The present disclosure relates to a system and a method for diagnosing abnormality of a battery cell by detecting abnormality in voltage of the battery cell.

### BACKGROUND

As signs of abnormal climate occur due to emission of greenhouse gas, electrical energy that does not emit greenhouse gas is spotlighted. Also, internal combustion engines that drive vehicles with oil are expected to be gradually replaced by batteries and motors.

Electric vehicles are equipped with large-capacity batteries to make it possible to drive 500 km or more. The large-capacity batteries mounted on an electric vehicle are high-voltage batteries with a voltage of 300V or more. The high-voltage batteries are configured by assembling battery cells of single units.

A battery is provided with a Battery Management System (BMS) for monitoring electrical characteristics such as state of charge (SOC), state of health (SOH), voltage, current, and the like of the battery. The BMS may monitor whether there is an abnormality in the battery while the battery is being used, after the battery is used, while the battery is being charged, or after the battery is charged. The BMS may control intensity of the voltage and current of the battery.

Meanwhile, a high-voltage battery connects 2 or 3 battery cells in a parallel structure to increase capacity (Ah). However, although one of the battery cells connected in parallel is excessively deteriorated or an internal short circuit occurs and a voltage drop occurs, since the BMS measures an average voltage of the 2 or 3 battery cells, all the battery cells connected in parallel may be diagnosed as being normal. Therefore, there is a problem in that it takes a long time to diagnose an abnormality in a battery cell until the average voltage of the battery cells connected in parallel drops significantly as the voltage of a defective battery cell drops significantly.

The subject matter described above as the background art is only for improving understanding of the background of the present disclosure. The above should not be taken as an admission that the subject matter corresponds to the prior art already known to those having ordinary skill in the art.

### SUMMARY

The present disclosure has been proposed to solve the above problems. Objects of the present disclosure are to provide a system and a method for diagnosing abnormality of a battery cell. Thus, the abnormality of the battery cell may be diagnosed at an early stage.

A system for diagnosing abnormality of a battery cell according to the present disclosure for accomplishing the above objects is provided. The system includes a plurality of battery cells of a battery and a sensing board connected to the plurality of battery cells. The system also includes a plurality of switches provided respectively between each battery cell and the sensing board and configured to electrically connect or disconnect the respective battery cells and the sensing board. The system also includes a controller configured to measure voltage of any one battery cell by electrically connecting the one battery cell among the plurality of battery cells to the sensing board and disconnecting remaining battery cells. The controller is further configured to diagnose each of the plurality of battery cells based on voltage drop in each battery cell.

The controller may calculate the voltage drop in each battery cell by storing the voltage measured for each battery cell and measuring and storing again the voltage of the battery cell after a predetermined time has elapsed.

The controller may count the number of times where the voltage drop, calculated in each battery cell, is equal to or greater than a threshold. The controller may further diagnose that an abnormality has occurred in the corresponding diagnosed battery cell when the counted number of times is accumulated to be more than a predetermined number of times.

The controller may sum up the voltage drop in each battery cell as many times as a preset number. The controller may further diagnose that there is an abnormality in a corresponding battery cell when the voltage drop in each battery cell is greater than a reference value.

The controller may measure the voltage of the battery cell when a state of charge (SOC) of the battery exceeds 50% and a temperature of the battery exceeds 10° C.

The controller may monitor any one or more among voltage, current, temperature, SOC, or state of health (SOH) of the battery cell for a predetermined period of time after using or charging of the battery cell is completed. The controller may further measure the voltage of the battery cell after the monitoring is completed.

The controller may calculate the voltage drop in the battery cells when states of charge (SOCs) of the battery cells are equal.

A method of diagnosing abnormality of a battery cell according to the present disclosure for accomplishing the above objects is provided. The method includes measuring, by a controller, voltage of any one battery cell by electrically connecting any one battery cell among a plurality of battery cells to a sensing board and disconnecting the remaining battery cells. The method further includes calculating voltage drop in the battery cell. The method further includes diagnosing the battery cell based on the voltage drop in the battery cell.

Measuring the voltage of any one battery cell may include controlling, by the controller, any one switch among a plurality of switches to connect the sensing board and the battery cell. Measuring the voltage of any one battery cell may further include controlling, by the controller, the remaining switches to disconnect the sensing board and the battery cell. Measuring the voltage of any one battery cell may further include storing the measured voltage of the battery cell, by the controller.

Calculating the voltage drop in the battery cell may include calculating, by the controller, the voltage drop by comparing a previously stored voltage of the battery cell with a currently stored voltage of the battery cell.

Calculating the voltage drop in the battery cell may include calculating the voltage drop by comparing voltages measured and stored in an equal SOC of the battery cell.

Diagnosing the battery cell may include counting, by the controller, the number of times where the voltage drop, calculated in each battery cell, is equal to or greater than a threshold. Diagnosing the battery cell may further include diagnosing, by the controller, that an abnormality has occurred in the corresponding battery cell when the counted number of times is accumulated to be more than a predetermined number of times, by the controller.

Diagnosing the battery cell may include the summing up, by the controller, the voltage drop in each battery cell as many times as a preset number. Diagnosing the battery cell may further include diagnosing, by the controller, that there is an abnormality in a corresponding battery cell when the voltage drop in each battery cell is greater than a reference value.

The method of diagnosing abnormality of the battery cell may further include, before measuring the voltage of any one battery cell, determining, by the controller, whether a SOC of the battery exceeds 50% and a temperature of the battery exceeds 10° C.

The method of diagnosing abnormality of a battery cell may further include, before measuring the voltage of any one battery cell, monitoring any one or more among voltage, current, temperature, SOC, and SOH of the battery cell.

According to the system and the method for diagnosing abnormality of a battery cell of the present disclosure, because defective battery cells can be detected and a user can be notified at an early stage, there is an advantage in that stability in using batteries can be enhanced by inducing taking measures such as repair, replacement, or the like.

### BRIEF DESCRIPTION OF THE DRAWINGS

FIG. 1 is a view showing the circuit and a configuration of a system for diagnosing abnormality of a battery cell according to an embodiment of the present disclosure.

FIG. 2 is a view showing connection of a circuit for measuring voltage of a plurality of battery cells.

FIG. 3 is a view showing connection of a circuit for measuring voltage of a plurality of battery cells.

FIG. 4 is a view showing a circuit diagram for measuring voltage of a battery cell according to the prior art.

FIG. 5 is a view showing a circuit diagram for measuring voltage of a battery cell according to the prior art.

FIGS. 6 and 7 are flowcharts illustrating a method of diagnosing abnormality of a battery cell according to an embodiment of the present disclosure.

### DETAILED DESCRIPTION

Hereinafter, the embodiments disclosed in this specification are described in detail with reference to the accompanying drawings. The same or similar components are given the same reference numerals throughout the drawings, and duplicate descriptions thereof have been omitted.

In describing the embodiments disclosed in this specification, where it has been determined that the detailed descriptions of related known techniques may obscure the gist of the embodiments disclosed in this specification, the detailed descriptions have been omitted. In addition, the accompanying drawings are only to aid in understanding the embodiments disclosed in this specification. The technical spirit disclosed in this specification is not limited by the accompanying drawings and should be understood to include all changes, equivalents, and substitutes included in the spirit and technical scope of the present disclosure.

Although terms including ordinal numbers, such as first, second, and the like, may be used to describe various components, the components are not limited by the terms. The terms are used only for the purpose of distinguishing one component from another.

Singular expressions include plural expressions unless the context clearly dictates otherwise.

In this specification, terms such as “comprise”, “have”, and the like are intended to indicate the presence of a feature, a number, a step, an operation, a component, a part, or a combination thereof described in the specification. It should be understood that the terms do not preclude the possibility of the presence or addition of one or more other features, numbers, steps, operations, components, parts, or combinations thereof.

When a component is mentioned as being “connected” or “coupled” to another component, it should be understood that, although the component may be directly connected or coupled to another component, other components may exist in the middle. On the contrary, when a component is mentioned as being “directly connected” or “directly coupled” to another element, it should be understood that no other component exists in the middle.

Meanwhile, the controller that appears in the disclosure of this application may include a communication device for communicating with other controllers or sensors to control relevant functions, a memory for storing operating systems or logic instructions and input/output information, and one or more processors for conducting determinations, operations, decisions, and the like. The controller is desirably a Battery Management System (BMS) that monitors and manages battery cells, battery modules, batteries, battery cooling systems, and the like. When a component, device, element, or the like of the present disclosure is described as having a purpose or performing an operation, function, or the like, the component, device, element, or the like should be considered herein as being “configured to” meet that purpose or to perform that operation or function. Each component, device, element, and the like may separately embody or be included with a processor and a memory, such as a non-transitory computer readable media, as part of the apparatus.

The system for diagnosing abnormality of a battery cell according to the present disclosure for achieving the above objects includes a plurality of battery cells 100. The system also includes a sensing board 500 connected to the plurality of battery cells. The system also includes a plurality of switches 200 provided respectively between each battery cell 100 and the sensing board 500 to electrically connect or disconnect the battery cell 100 and the sensing board 500. The system also includes a controller 600 for electrically connecting any one battery cell 100 among the plurality of battery cells 100 to the sensing board 500 and disconnecting the remaining battery cells 100 to measure voltage of the one isolated battery cell 100. The controller 600 is also configured to diagnose each of the plurality of battery cells 100 based on a voltage drop in each battery cell.

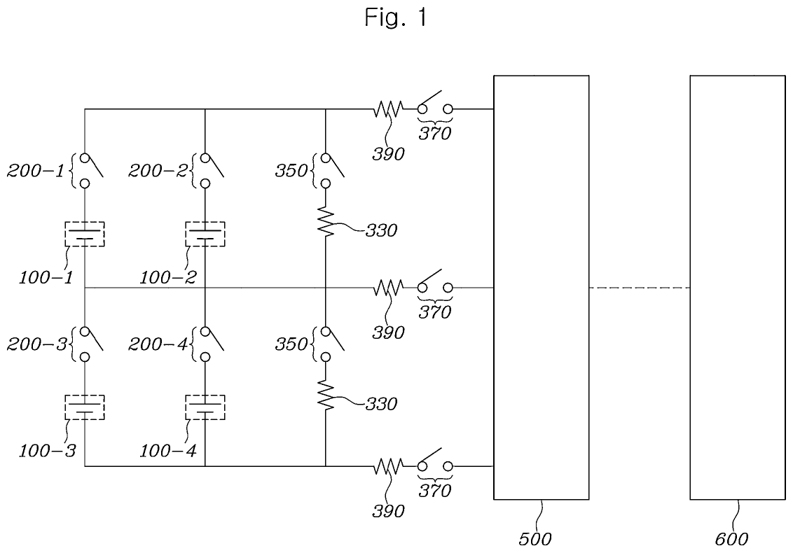

FIG. 1 is a view showing the circuit and a configuration of a system for diagnosing abnormality of a battery cell according to an embodiment of the present disclosure. It is shown in FIG. 1 that two battery cells can be connected in parallel. The battery cell 100 is shown as a box having + and − poles in FIG. 1. Referring to FIG. 1, battery cells 100-1 and 100-2 are connected to each other in parallel, and battery cells 100-3 and 100-4 are connected to each other in parallel. However, the parallel structure of the battery cells 100 is not limited thereto and connecting three or more battery cells 100 in parallel should also be considered as a possible embodiment.

Meanwhile, a plurality of battery cells 100 is connected to the sensing board 500. Because a connection switch 370 is provided between each of the plurality of battery cells 100 and the sensing board 500, each of the plurality of battery cells 100 may be electrically connected to the sensing board 500 by the operation of the connection switch 370. A circuit equivalent resistor 390 is provided adjacent to the connection switch. The circuit equivalent resistor 390 is a simplification of complex electrical circuits, designed to make the overall circuit easier to understand. It serves as a representation, allowing the circuit to be expressed in terms of a single, simplified resistance value.

A Battery Monitoring Integrated Circuit (BMIC) is provided in the sensing board 500 to measure the voltage of the battery cells 100 through the BMIC. The BMIC may transfer the measured voltage of the battery cell 100 to the controller 600 described below in detail.

In addition, in the system for diagnosing abnormality of a battery cell, a balancing switch 350 and a balancing resistor 330 may be provided to suppress deterioration of the battery cells through balancing of the battery cells. For example, when the voltage of battery cell 100-1 is higher than the voltage of battery cell 100-2, in order to drop the voltage of battery cell 100-1, the battery cell 100-1 and the balancing resistor 350 may be electrically connected by handling the balancing switch 350 and switch 200-1 to relieve part of the voltage of battery cell 100-1 through the balancing resistor 330.

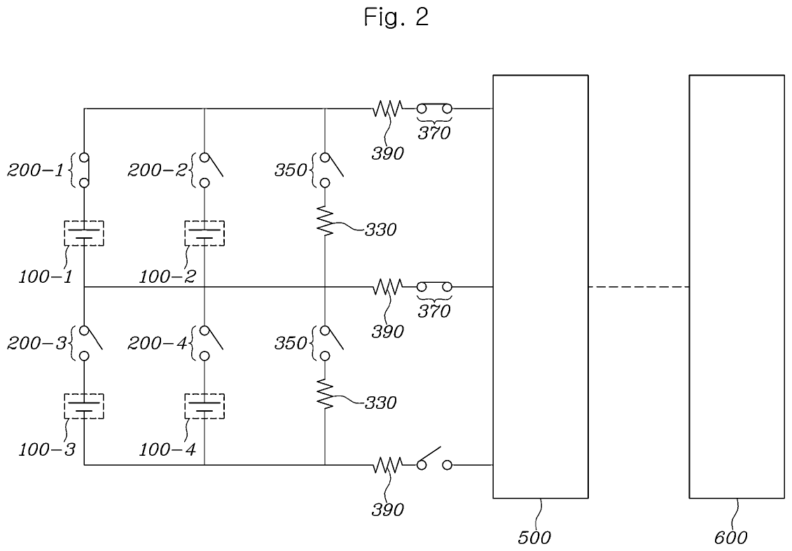

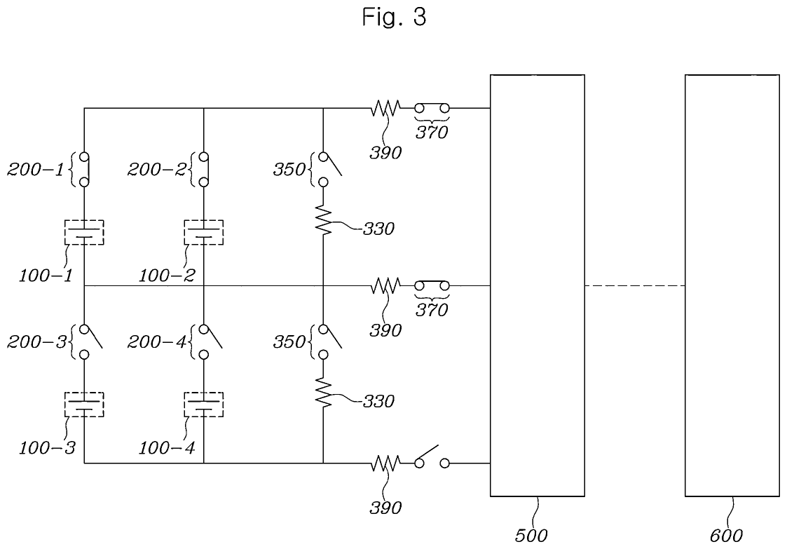

FIGS. 2 and 3 show a circuit diagram depicting the connection for measuring the voltage of a plurality of battery cells 100. The system for diagnosing abnormality of a battery cell 100 according to an embodiment of the present disclosure may measure individual voltage of the battery cell 100-1 when the circuit is connected as shown in FIG. 2.

Specifically, as shown in FIG. 2, the switch 200-1 and the connection switch 370 are handled to electrically connect the battery cell 100-1 and the sensing board 500 to measure individual voltage of the battery cell 100-1.

When the circuit is connected as shown in FIG. 3, battery cell 100-1 and battery cell 100-2 are connected in parallel. An average voltage of the voltage values of battery cell 100-1 and battery cell 100-2 may be measured.

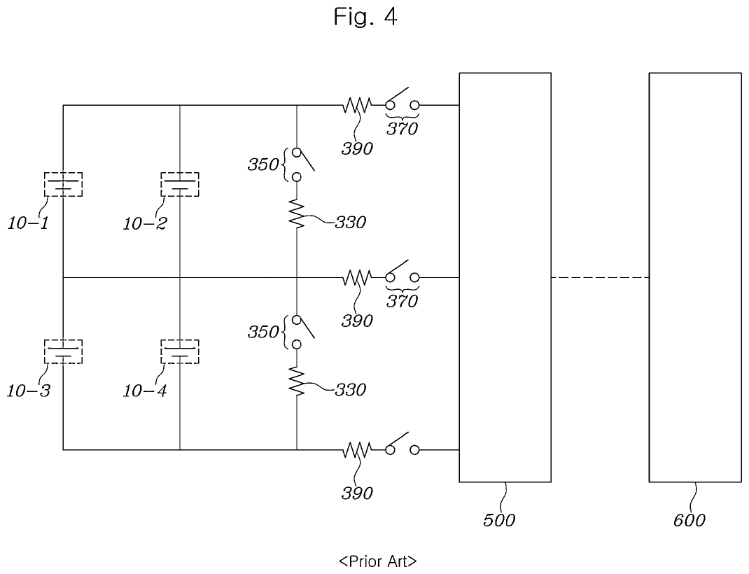

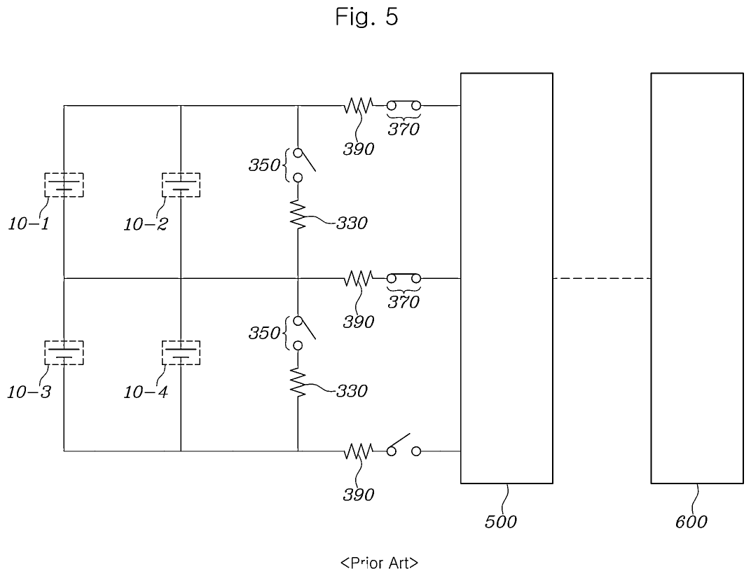

FIGS. 4 and 5 show a circuit diagram for measuring voltage of a battery cell according to the prior art. Referring to the circuit diagram in FIG. 5, when voltage of the battery cell 10 is measured according to the prior art, there is no choice but to measure the average voltage of battery cell 10-1 and battery cell 10-2. Accordingly, although deterioration of battery cell 10-1 is excessive, when battery cell 10-2 is a normal cell, the average voltage is measured to be at a good level. Therefore, whether an abnormality has occurred in either battery cell 10-1 or 10-2 may be grasped only when deterioration of battery cell 10-1 is further progressed.

The system for diagnosing abnormality of a battery cell according to an embodiment of the present disclosure includes a plurality of switches 200 provided respectively between each battery cell 100 and the sensing board 500 to electrically connect or disconnect the battery cell 100 and the sensing board 500 to measure voltage of individual cells as shown in FIG. 2.

To perform this, the controller 600 electrically connects any one battery cell 100 among the plurality of battery cells to the sensing board 500 and disconnects the remaining battery cells 100 to isolate one battery cell and measure the voltage of the one battery cell 100.

Specifically, referring to FIG. 2, when it is desired to measure the voltage of battery cell 100-1, the voltage of battery cell 100-1 may be measured by disconnecting the electrical connection between battery cell 100-2 and the sensing board 500 and also disconnecting the electrical connection between battery cells 100-3 and 100-4 connected to battery cell 100-1 in series and the sensing board 500.

Meanwhile, the controller 600 may diagnose whether an abnormality has occurred in each of the battery cells 100 based on the drop in voltage of the battery cells 100 individually measured as described above. Details of diagnosing abnormality in the battery cells 100 are described below.

In this way, the system for diagnosing abnormality of a battery cell according to the present disclosure makes it possible to measure the voltage of each battery cell 100 individually so that abnormality of each battery cell 100 may be identified or determined within a short period of time.

In addition, in the prior art, although an abnormality occurs in the average voltage of the battery cells, it needs to be diagnosed again in detail to determine in which battery cell, among the battery cells connected in parallel, the abnormality has occurred. Therefore, the time required for diagnosing abnormality of a battery cell is a little bit long, i.e., undesirable. However, as the voltage is measured for each battery cell in the present disclosure, there is an advantage in that a battery cell in which an abnormality is diagnosed may be specifically identified.

Meanwhile, the controller 600 may calculate the voltage drop in each cell by storing the voltage measured for each battery cell 100 and by measuring and storing again the voltage of the battery cell 100 after a predetermined time has elapsed.

Specifically, the controller 600 may measure the voltage of the battery cell 100 at regular time intervals to calculate voltage drop in the battery cell 100. For example, the controller 600 may measure the voltage of the battery cell 100 after using or charging of the battery is completed. The controller 600 may also measure and store again the voltage of the battery cell 100 when 5 or 10 hours have elapsed since the voltage of the battery cell 100 is measured.

Accordingly, the controller 600 may calculate the voltage drop in the battery cell 100 by comparing the voltage of the battery cell 100 stored previously with the voltage of the battery cell 100 stored currently (or thereafter).

It is desirable that the controller 600 measures and stores the voltage of the battery cell 100 while the battery is not used for safety reasons.

Hereinafter, calculation of the voltage drop in the battery cell is explained using an example.

For example, when it is assumed that operation of an electric vehicle is finished at 10:00 and measurement of the voltage of the battery cell begins at 12:00, measurement of the voltage of the battery cell may begin again at 17:00, when 5 hours have elapsed after 12:00. However, the voltage of the battery cell may be measured at 17:00 in a situation in which the battery is not in use (i.e., in operation or the like of the electric vehicle).

At this point, the vehicle has not been operated between 12:00 and 17:00, and it is desirable to measure the voltage drop when the state of charge (SOC) of the battery measured at 12:00 is equal to or slightly different from the SOC of the battery measured at 17:00.

In other words, since voltage of a battery may change according to the SOC, it is desirable to measure the voltage drop when the states of charge (SOCs) are equal or slightly different.

Here, the predetermined time may be determined by the controller 600. The controller 600 may store and learn information about the operation of the electric vehicle. Therefore, the controller 600 may appropriately adjust the predetermined time by storing and learning information about the time required for the user to turn off the motor of the electric vehicle and turn on the motor of the electric vehicle again.

Meanwhile, the controller 600 may count the number of times where the voltage drop calculated in each battery cell 100 is equal to or greater than a threshold. The controller 600 may also diagnose that an abnormality has occurred in the corresponding battery cell 100 when the counted number of times is accumulated to be more than a predetermined number of times.

Specifically, it is assumed that the measured and stored voltage of battery cell 100-1 is as shown in Table 1 below, and the threshold is 3 mV. When the drop of voltage exceeding the threshold is accumulated to be more than 3 times, it is diagnosed that there is an abnormality in the battery cell 100. For the convenience of explanation, an electric vehicle in which the SOC of the battery is not changed is assumed.

TABLE 1

| Cell | | Voltage | Voltage drop | Threshold |
|---|---|---|---|---|
| 100-1 | SOC | (V) | (mV) | count |
| 1^{st} | 90% | 4.0 | — | — |
| 2^{nd} | 90% | 3.996 | 4 | 1 |
| 3^{rd} | 90% | 3.995 | 1 | 1 |
| 4^{th} | 90% | 3.985 | 10 | 2 |
| 5^{th} | 90% | 3.970 | 15 | 3 |
| 6^{th} | 90% | 3.970 | 0 | 3 |

Referring to Table 1, since the number of times of measuring the voltage drop in battery cell 100-1 is more than 3 mV is accumulated to be 3 times or more, the controller may determine that battery cell 100-1 is a battery cell having an abnormality.

However, since the SOC of the battery is a value that may constantly change according to operation and charging of the electric vehicle, when the SOC of the battery changes, Table 2 is referred to.

TABLE 2

| Cell | | Voltage | Voltage drop | Threshold |
|---|---|---|---|---|
| 100-1 | SOC | (V) | (mV) | count |
| 1^{st} | 90% | 4.0 | — | |
| 2^{nd} | 90% | 3.996 | 4 | 1 |
| 3^{rd} | 65% | 3.857 | — | |
| 4^{th} | 65% | 3.851 | 6 | 2 |
| 5^{th} | 90% | 3.991 | — | |
| 6^{th} | 90% | 3.989 | 2 | 2 |
| 7^{th} | 70% | 3.878 | — | |
| 8^{th} | 70% | 3.873 | 5 | 3 |
| 9^{th} | 90% | 3.995 | — | |

Referring to Table 2, voltage drop is calculated through the 1st and 2nd voltage measurements where the SOC is 90%. Since SOCs of the 2nd and 3rd voltage measurements are different, voltage drop is not measured. However, since SOCs of the 3rd and 4th measurements are equal, voltage drop is measured. Thereafter, since SOCs of the 4th and 5th measurements are different, voltage drop is not measured, and since SOCs of the 5th and 6th measurements are equal, voltage drop is measured. As a result, since the count of exceeding the threshold is 3, battery cell 100-1 is diagnosed as having an abnormality.

On the other hand, as an embodiment different from the above one, the controller 600 may sum up the voltage drop in each battery cell 100 as many times as a preset number. The controller 600 may then diagnose that there is an abnormality in a corresponding battery cell 100 when the voltage drop in each cell is greater than a reference value.

TABLE 3

| Cell | | Voltage | Voltage drop | Sum of voltage |
|---|---|---|---|---|
| 100-1 | SOC | (V) | (mV) | drops (mV) |
| 1^{st} | 90% | 4.0 | — | — |
| 2^{nd} | 90% | 3.996 | 4 | 4 |
| 3^{rd} | 90% | 3.995 | 1 | 5 |
| 4^{th} | 90% | 3.985 | 10 | 15 |
| 5^{th} | 90% | 3.970 | 15 | 30 |
| 6^{th} | 90% | 3.970 | 0 | 0 |

Referring to Table 3, the voltage drops are summed up as shown in Table 3. When the voltage drop in each cell is greater than a reference value, it may be diagnosed that there is an abnormality in the corresponding battery cell 100. For example, when the sum of voltage drops is 15 mV or more, it may be diagnosed that there is an abnormality in the corresponding battery cell 100.

As a result, in the case of battery cell 100-1 in Table 3, since the voltage drop is more than 15 mV, the battery cell may be diagnosed as having an abnormality.

In the same manner in this embodiment, it is desirable to calculate voltage drop by comparing voltage measurements measured under the condition of equal SOC. However, since the SOC of the battery is a value that may constantly change according to operation and charging of the electric vehicle, when the SOC of the battery changes, Table 4 is referred to.

Table 4 is a table presented as an example to explain a case of diagnosing abnormality in the battery cell 100 when the SOC of the battery is changed.

TABLE 4

| Cell | | Voltage | Voltage drop | Sum of voltage |
|---|---|---|---|---|
| 100-1 | SOC | (V) | (mV) | drops (mV) |
| 1^{st} | 90% | 4.0 | — | |
| 2^{nd} | 90% | 3.996 | 4 | 4 |
| 3^{rd} | 65% | 3.857 | — | |
| 4^{th} | 65% | 3.851 | 6 | 10 |
| 5^{th} | 90% | 3.991 | — | |
| 6^{th} | 90% | 3.989 | 2 | 12 |
| 7^{th} | 70% | 3.878 | — | |
| 8^{th} | 70% | 3.873 | 5 | 17 |
| 9^{th} | 90% | 3.995 | — | |

When the SOC is changed as shown in Table 4, it is desirable to calculate voltage drop in each cell by comparing voltage measurements measured under the condition of equal SOC.

Voltage drop is calculated through the 1st and 2nd voltage measurements where the SOC is 90%. Since SOCs of the 2nd and 3rd voltage measurements are different, voltage drop is not measured. However, since SOCs of the 3rd and 4th measurements are equal, voltage drop is measured. Thereafter, since SOCs of the 4th and 5th measurements are different, voltage drop is not measured, and since SOCs of the 5th and 6th measurements are equal, voltage drop is measured. As a result, since the sum of voltage drops is larger than 15 mV, battery cell 100-1 is diagnosed as having an abnormality.

In the above embodiments, counting the number of times exceeding the threshold or summing up the voltage drops for a specific battery cell 100 is repeated for a predetermined number of times. When the count or the summation count exceeds a predetermined number, the calculated value of the voltage drop is reset. Also, abnormality of the battery cell 100 may be diagnosed by calculating again the voltage drop from the beginning and counting the number of times exceeding the threshold or summing up the voltage drops.

Meanwhile, the controller 600 may measure the voltage of the battery cell 100 when the SOC of the battery exceeds 50% and the temperature of the battery exceeds 10° C. Since the battery resistance value does not change significantly when the SOC of the battery exceeds 50% and the temperature of the battery exceeds 10° C. and is close to room temperature, it is desirable to measure the voltage of the battery cell 100 under the above conditions.

The controller 600 monitors any one or more among the voltage, current, temperature, SOC, and state of health (SOH) of the battery for a predetermined period of time after using or charging of the battery is completed. The controller 600 may also measure voltage of the battery cell 100 after the monitoring is completed.

Specifically, the controller 600 may confirm the state of the battery after operation of the electric vehicle is finished. For example, the controller 600 may measure the voltage of the battery cell 100 after monitoring the overall battery performance, such as the voltage, current, temperature, SOC, and SOH of the battery, and matters related to battery safety.

It takes about 1 to 2 hours for monitoring, and this is time enough for the battery to be stabilized at room temperature. In addition, since it is general that charging is performed after driving of the electric vehicle is completed, after charging of the battery is completed, the controller 600 may measure the voltage of the battery cell 100 after monitoring the overall battery performance, such as the voltage, current, temperature, SOC, and SOH of the battery, and matters related to battery safety.

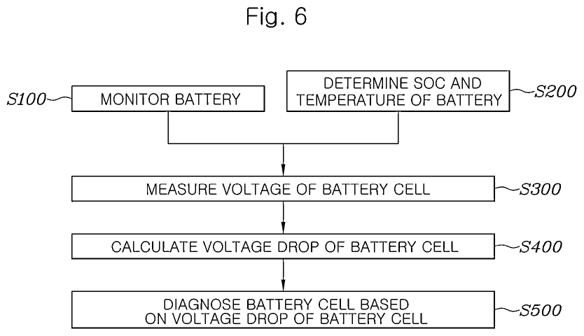

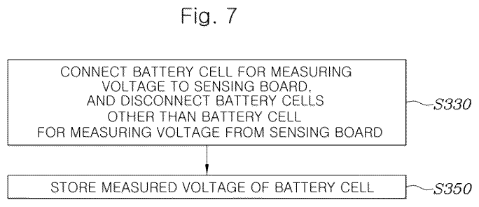

Hereinafter, a method of diagnosing abnormality of a battery cell is described with reference to FIGS. 6 and 7.

FIGS. 6 and 7 are flowcharts illustrating a method of diagnosing abnormality of a battery cell according to an embodiment of the present disclosure. The method of diagnosing abnormality of a battery cell for achieving the above objects includes measuring by the controller 600, voltage of any one battery cell 100 by electrically connecting and isolating one battery cell 100 among a plurality of battery cells 100 to the sensing board 500 and disconnecting the remaining battery cells 100 (S300). The method also includes calculating voltage drop in the battery cell 100 (S400) and diagnosing the battery cell 100 based on the voltage drop in the battery cell 100 (S500).

Referring to FIG. 7, measuring the voltage of the battery cell (S300) may include controlling, by the controller 600, any one switch 200 among a plurality of switches to connect the sensing board 500 and the one battery cell 100 to be isolated and controlling the remaining switches 200 to disconnect the sensing board 500 and the battery cell 100 (S330). Measuring the voltage (S300) may also include storing, by the controller 600, the measured voltage of the battery cell 100 (S350).

Calculating the voltage drop in the battery cell 100 (S400) may include calculating, by the controller 600, the voltage drop by comparing the previously stored voltage of the battery cell 100 with the currently stored voltage of the battery cell 100.

Diagnosing the battery cell 100 (S500) may include counting, by the controller 600, the number of times where the voltage drop calculated in each battery cell 100 is equal to or greater than a threshold. Diagnosing the battery cell (S500) may also include diagnosing that an abnormality has occurred in the corresponding battery cell 100 when the count is accumulated to be more than a predetermined number of times.

As another example, diagnosing the battery cell 100 (S500) may include, by the controller 600, summing up the voltage drop in each battery cell 100 as many times as a preset number and diagnosing that there is an abnormality in a corresponding battery cell 100 when the voltage drop in each cell is greater than a reference value.

Before measuring the voltage of the battery cell (S300), determining whether the state of charge (SOC) of the battery exceeds 50% and the temperature of the battery exceeds 10° C. by the controller 600 (S200) may be further included.

In addition, before measuring the voltage of the battery cell (S300), monitoring any one or more among the voltage, current, temperature, SOC, and state of health (SOH) of the battery (S100) may be further included.

Although the present disclosure has been shown and described in relation to specific embodiments, it should be apparent to those having ordinary skill in the art that the present disclosure can be variously improved and modified without departing from the technical spirit of the present disclosure provided by the claims below.

### DESCRIPTION OF REFERENCE NUMERALS

100: battery cell
200: switch
330: balancing resistor
350: balancing switch
500: sensing board
600: controller

What is claimed is:

1. A system for diagnosing abnormality of a battery cell, the system comprising:
a battery having a plurality of battery cells;
a sensing board connected to the plurality of battery cells;
a plurality of switches provided respectively between each cell of the plurality of battery cells and the sensing board and configured to electrically connect or disconnect each cell and the sensing board; and
a controller, wherein the controller is configured to
measure voltage of any one battery cell of the plurality of battery cells by electrically connecting the one battery cell to the sensing board and disconnecting remaining battery cells of the plurality of battery cells from the sensing board, and
diagnose each cell of the plurality of battery cells based on a voltage drop in each cell.

2. The system according to claim 1, wherein the controller is configured to calculate the voltage drop in each cell by storing the voltage measured for each cell and by measuring and storing again the voltage of each cell after a predetermined time has elapsed.

3. The system according to claim 2, wherein the controller is further configured to:
count the number of times where the voltage drop calculated in each cell is equal to or greater than a threshold; and
diagnose that an abnormality has occurred in a diagnosed battery cell of the plurality of battery cells when the counted number of times for the diagnosed battery cell is more than a predetermined number of times.

4. The system according to claim 2, wherein the controller is further configured to:
sum up the voltage drop in each cell as many times as a preset number; and
diagnose that there is an abnormality in a diagnosed battery cell of the plurality of battery cells when the voltage drop in the diagnosed battery cell is greater than a reference value.

5. The system according to claim 1, wherein the controller measures the voltage of each cell when a state of charge (SOC) of the battery exceeds 50% and a temperature of the battery exceeds 10° C.

6. The system according to claim 1, wherein the controller is further configured to:
monitor any one or more among voltage, current, temperature, SOC, or state of health (SOH) of the battery for a predetermined period of time after using or charging of the battery is completed; and
measure the voltage of each cell after the monitoring is completed.

7. The system according to claim 1, wherein the controller is further configured to calculate the voltage drop in each cell when states of charge (SOCs) of the battery are equal.

8. A method of diagnosing abnormality of a battery cell of a battery, the method comprising:
measuring, by a controller, voltage of any one battery cell among a plurality of battery cells of the battery by electrically connecting the one battery cell to a sensing board and disconnecting remaining battery cells of the plurality of battery cells from the sensing board;
calculating voltage drop in the one battery cell; and
diagnosing the one battery cell based on the voltage drop in the one battery cell.

9. The method according to claim 8, wherein measuring the voltage of any one battery cell includes:
controlling, by the controller, one switch among a plurality of switches to connect the sensing board and the one battery cell;
controlling, by the controller, remaining switches of the plurality of switches to respectively disconnect the sensing board and the remaining battery cells; and
storing, by the controller, the measured voltage of the one battery cell.

10. The method according to claim 9, wherein calculating the voltage drop in the one battery cell includes calculating, by the controller, the voltage drop by comparing a previously stored voltage of the one battery cell with a currently stored voltage of the one battery cell.

11. The method according to claim 10, wherein calculating the voltage drop in the one battery cell includes calculating the voltage drop by comparing voltages measured and stored in an equal state of charge (SOC) of the battery.

12. The method according to claim 8, wherein diagnosing the one battery cell includes:
counting, by the controller, the number of times where the voltage drop, calculated in each battery cell of the plurality of battery cells, is equal to or greater than a threshold; and
diagnosing, by the controller, that an abnormality has occurred in the one battery cell when the counted number of times is more than a predetermined number of times for the one battery cell.

13. The method according to claim 8, wherein diagnosing the one battery cell includes:
summing up, by the controller, the voltage drop in each battery cell of the plurality of battery cells as many times as a preset number; and
diagnosing, by the controller, that there is an abnormality in the one battery cell when the voltage drop in the one battery cell is greater than a reference value.

14. The method according to claim 8, further comprising, before measuring the voltage of any one battery cell, determining, by the controller, whether a SOC of the battery exceeds 50% and a temperature of the battery exceeds 10° C.

15. The method according to claim 8, further comprising, before measuring the voltage of any one battery cell, monitoring any one or more among voltage, current, temperature, SOC, and state of health (SOH) of the battery.
